(19) United States
(12) Patent Application Publication
(10) Pub. No.: US 2025/0393274 A1
(43) Pub. Date: Dec. 25, 2025

(54) Power Semiconductor Device and Method of Producing a Power Semiconductor Device

(71) Applicant: Infineon Technologies AG, Neubiberg (DE)

(72) Inventors: Murugalogeswaran Permal, Sungkai (MY); Anton Mauder, Kolbermoor (DE)

(21) Appl. No.: 19/237,118

(22) Filed: Jun. 13, 2025

(30) Foreign Application Priority Data
Jun. 19, 2024 (DE) 102024117326.2

(51) Int. Cl. H10D 62/60; H10D 8/00; H10D 8/01; H10D 12/00; H10D 12/01; H10D 30/01; H10D 30/66; H10D 62/10; H10D 64/00

(52) U.S. Cl. CPC H10D 62/60; H10D 8/043; H10D 8/045; H10D 8/411; H10D 12/038; H10D 12/415; H10D 12/481; H10D 30/0291; H10D 30/665; H10D 62/124; H10D 64/111

(57) ABSTRACT

A power semiconductor device includes: first and second load terminals at respective front and back sides of a semiconductor body; in the semiconductor body and electrically connected with the first load terminal at the front side within an active region, a doped front side region of a second conductivity type; in the semiconductor body within an edge termination region, a VLD region of the second conductivity type coupled to the doped front side region and having a laterally varying dopant concentration that decreases in a direction from the active region towards a chip edge; at the front side, in the edge termination region, adjacent to the first load terminal and laterally overlapping with the VLD region, an insulation layer; and, above the insulation layer, in the edge termination region and laterally overlapping with the VLD region at least partially, a conductor coupled to a potential of the first load terminal.

### TECHNICAL FIELD

This specification refers to embodiments of a power semiconductor device and to embodiments of a method of producing a power semiconductor device. The power semiconductor device has a VLD edge termination configuration that may exhibit a dynamic ruggedness.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device comprises a semiconductor body configured to conduct a forward load current along a load current path between two load terminals of the device. The load current is conducted by means of an active region of the power semiconductor device. The active region is surrounded by an edge termination region, which is terminated by an edge of the chip.

In case of a controllable power semiconductor device, e.g., a transistor, the load current path may be controlled by means of insulated electrodes, commonly referred to as gate electrodes. For example, upon receiving a corresponding control signal, e.g., from a driver unit and via a control terminal of the device, the control electrodes may set the power semiconductor device in one of a forward conducting state and a blocking state.

Furthermore, some devices provide for reverse load current capability; i.e., the active region of the semiconductor body is further configured to conduct a reverse load current along a reverse load current path between the two load terminals of the device. For example, the RC (Reverse Current) IGBT is one representative of such devices. In an RC IGBT, a single chip unites an IGBT structure and a diode structure.

In a typical IGBT design, said gate electrodes frequently are accommodated in a trench structure that extends into the semiconductor body. The trench structure spatially confines portions of the semiconductor body, typically referred to as mesas, in which conductive channels may be formed that allow flow of the forward load current. The conductive channels, typically based on a semiconductor source region and a semiconductor body region of opposite conductivity type as the source region, are controlled based on the adjacent control electrodes.

It has been observed that during bipolar power device switch off, an excess charge still present from previous conduction mode is removed which may lead to a high hole current density towards a front side metal pad that is part of the first load terminal connected to a semiconductor anode region, for example. Regarding a VLD (variation of the lateral doping) edge termination, the hole density during commutation may exceed the concentration of the VLD doping, which may lead to increased electric field at an edge of the anode region and thus to a potential destruction of the device. To address this issue, the concentration of excess charge in the termination region during conduction mode can be reduced by a missing cathode/emitter region underneath the edge termination on the rear side. However, such blocked cathode/emitter region may require costly processing steps.

### SUMMARY

According to an embodiment, a power semiconductor device comprises: an active region surrounded by an edge termination region, wherein the edge termination region is terminated by a chip edge; a semiconductor body extending in both the active region and the edge termination region and comprising a semiconductor drift region of a first conductivity type; a first load terminal at a front side of the semiconductor body; a second load terminal at a back side of the semiconductor body opposite to the first side, wherein the power semiconductor device is configured to conduct, in the active region and along a vertical direction, a load current between the first load terminal and the second load terminal; in the semiconductor body and electrically connected with the first load terminal at the front side within the active region, a doped front side region of a second conductivity type; in the semiconductor body within the edge termination region, a VLD region of the second conductivity type, wherein the VLD region is coupled to the doped front side region and exhibits a laterally varying dopant concentration that decreases in a direction from the active region towards the chip edge; at the front side, in the edge termination region, adjacent to the first load terminal and laterally overlapping with the VLD region, an insulation layer; and above the insulation layer, in the edge termination region and laterally overlapping with the VLD region at least partially, an electrically conductive conductor coupled to the electrical potential of the first load terminal.

According to another embodiment, a method of producing a power semiconductor device comprises forming the following components: an active region surrounded by an edge termination region, wherein the edge termination region is terminated by a chip edge; a semiconductor body extending in both the active region and the edge termination region and comprising a semiconductor drift region of a first conductivity type; a first load terminal at a front side of the semiconductor body; a second load terminal at a back side of the semiconductor body opposite to the first side, wherein the power semiconductor device is configured to conduct, in the active region and along a vertical direction, a load current between the first load terminal and the second load terminal; in the semiconductor body and electrically connected with the first load terminal at the front side within the active region, a doped front side region of a second conductivity type; in the semiconductor body within the edge termination region, a VLD region of the second conductivity type, wherein the VLD region is coupled to the doped front side region and exhibits a laterally varying dopant concentration that decreases in a direction from the active region towards the chip edge; at the front side, in the edge termination region, adjacent to the first load terminal and laterally overlapping with the VLD region, an insulation layer; and above the insulation layer, in the edge termination region and laterally overlapping with the VLD region at least partially, an electrically conductive conductor coupled to the electrical potential of the first load terminal.

In accordance with embodiments described herein, based the conductor, the front side metal can be extended towards termination region. During commutation, holes that move towards the anode can find the opposing charge in the conductor which is reducing the electric field at the anode edge. However, during static operation, the conductor stays without effect and static blocking is merely enabled by the VLD region. For example, a sufficient level of ruggedness at diode commutation may be reached by a conductor overlapping the anode region by 40 μm using an insulation layer thickness of 320 nm.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a horizontal projection of a power semiconductor device in accordance with one or more embodiments;

FIG. 2 schematically and exemplarily illustrates a vertical cross-section of a power semiconductor device in accordance with one or more embodiments;

FIG. 3 schematically and exemplarily illustrates a vertical cross-section of a power semiconductor device in accordance with one or more embodiments;

FIG. 4 schematically and exemplarily illustrates a vertical cross-section of a power semiconductor device in accordance with one or more embodiments; and

FIG. 5 schematically and exemplarily illustrates a dopant concentration profile of a power semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

The first conductivity type is opposite to the second conductivity type. In this specification, n-doped is referred to as “first conductivity type” while p-doped is referred to as “second conductivity type”. Alternatively, opposite doping relations can be employed so that the first conductivity type can be p-doped and the second conductivity type can be n-doped. A dopant dose may be defined as the integral over the dopant concentration of the atoms of the respective conductivity type within a respective doping region in a vertical direction Z. The dopant dose may be the amount of dopant implanted per area.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “conducting state” of the power semiconductor device while a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the power semiconductor device. The term “forward biased blocking state” therefore may refer to conditions with the power semiconductor device being in the blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 600V or even more, e.g., up to at least 1.2 kV, or even up to 6 kV or more, depending on the respective application.

For example, the term “power semiconductor device” as used in this specification is not directed to logic semiconductor devices that are used for, e.g., storing data, computing data and/or other types of semiconductor-based data processing.

For example, the power semiconductor device described below may be a single semiconductor chip, e.g., exhibiting a stripe cell configuration (or a cellular/needle cell configuration) and can be configured to be employed as a power component in a low-, medium- and/or high voltage application.

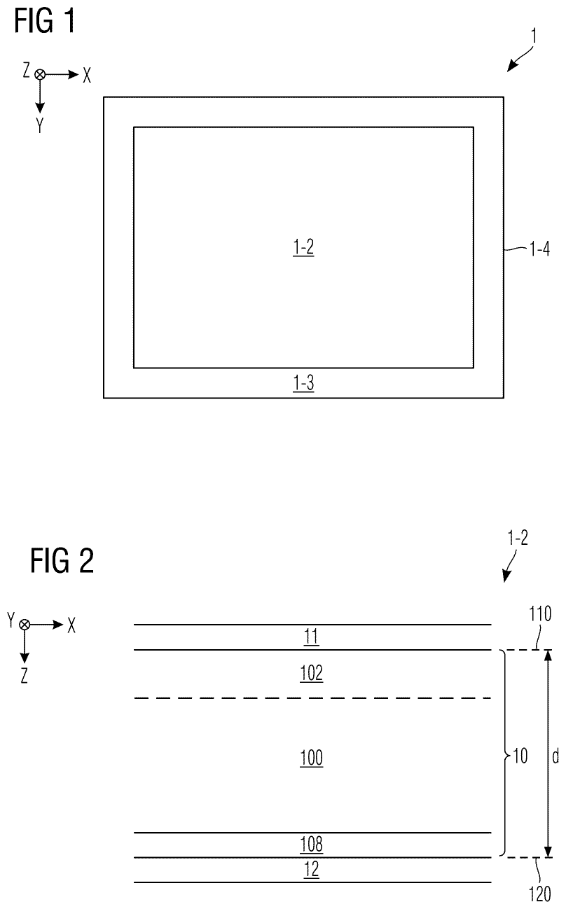

With respect to FIGS. 1 and 2, aspects related to a possible general configuration of the power semiconductor device 1 shall be explained:

The power semiconductor device 1, herein also referred to as “device 1”, comprises, e.g., in a single chip, a semiconductor body 10 configured to conduct, in an active region 1-2, a load current between a first load terminal 11 at a first side 110 of the semiconductor body 10 and a second load terminal 12 at a second side 120 of the semiconductor body 10. The device 1 can be, e.g., a diode, an IGBT (or a derivative thereof, such as RC IGBT) or, e.g., a MOSFET (or a derivative thereof). Accordingly, the first load terminal 11 may be an anode terminal, an emitter terminal or a source terminal, and the second load terminal 12 may be a cathode terminal, a collector terminal or a drain terminal.

As exemplarily illustrated in FIG. 1, the active region 1-2 of the device 1 is surrounded by an edge termination region 1-3. In the active region 1-2, a trench structure may form a cell field, e.g., in case of a MOSFET or an IGBT. If embodied as a diode, a trench structure is typically not provided.

The edge termination region 1-3 is typically not employed for load current conduction, as it is known to the skilled person. The edge termination region 1-3 is terminated by the chip edge 1-4.

As exemplarily illustrated in FIG. 2, the first side 110 and the second side 120 may be arranged opposite of each other. For example, the first side 110 is a front side of the device 1 and the second side 120 is a back side of the device 1. Accordingly, the device 1 may exhibit a vertical configuration according to which the load current within the device 1 follows a path in parallel to the vertical direction Z. The semiconductor body 10 may be sandwiched between the first load terminal 11 and the second load terminal 12 and exhibit a vertical extension d, e.g., in the range of 40 μm to 750 μm, depending, e.g., on the maximal blocking voltage the device 1 shall exhibit.

The device 1 further comprises a drift region 100 of a first conductivity type within the semiconductor body 10. Herein, the term “drift region” is employed with the meaning the skilled person typically associates therewith in the field of power semiconductor devices. For example, the vertical extension of the drift region 100 influences the voltage blocking capabilities (e.g., said maximal blocking voltage) of the device 1.

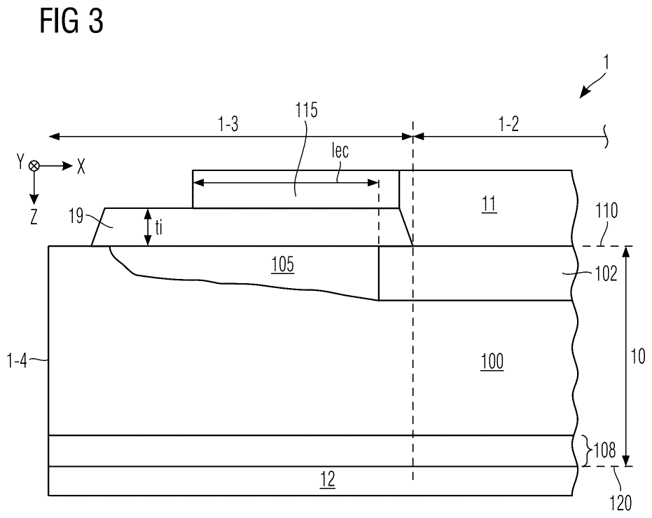

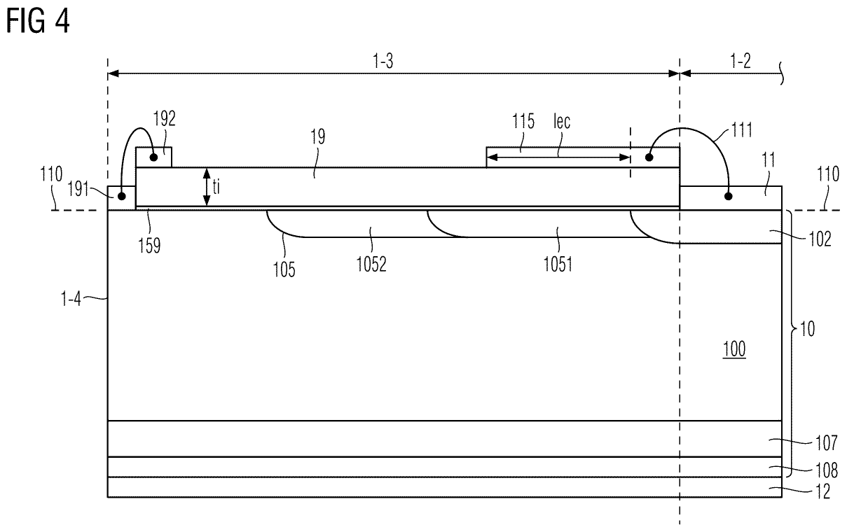

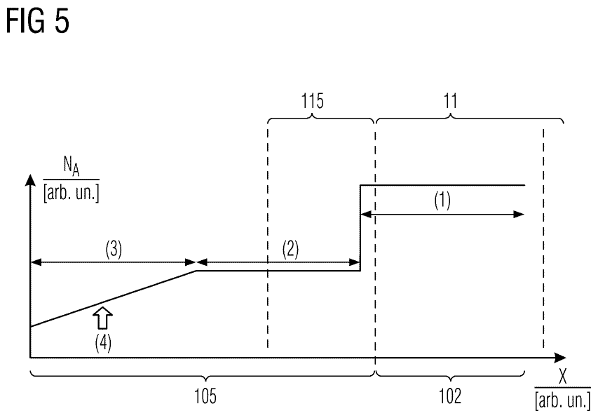

As illustrated schematically in FIG. 2 (and in FIGS. 3 and 4), at the front side 110, the semiconductor body 10 may comprise a doped front side region 102 of the second conductivity type electrically connected to the first load terminal 11. For example, the doped front side region is an anode region in contact with the first load terminal 11.

Further, at the back side 120, a doped back side region 108 of the semiconductor body 10 may be provided below the drift region 100. The adjoining doped back side region 108 is electrically connected with the second load terminal 12 and can be configured in accordance with the designated characteristic of the device 1. For example, the doped back side region 108 can be a cathode region of the first conductivity type, if the device 1 shall exhibit a diode or MOSFET configuration. Or, the doped back side region 108 can be an emitter region of the second conductivity type, if the device 1 shall exhibit an IGBT configuration. The doped region 108 can be arranged in contact with the second load terminal 12. If the device 1 shall exhibit an RC IGBT configuration, the doped region 108 can be an emitter region of the second conductivity type exhibiting subsections of the first conductivity type, as it is known to the skilled person.

If the device 1 shall exhibit a MOSFET configuration, the doped region 108 can be a highly doped region of the first conductivity type adjoining the second load terminal 12.

In addition, a (non-illustrated) field stop region of the first conductivity type can be provided between the drift region 100 and the doped back side region 108, wherein the field stop region exhibits a greater dopant concentration than the drift region 100.

Both FIG. 3 and FIG. 4 schematically and exemplarily illustrate a respective vertical cross-section of the power semiconductor device 1 in accordance with some embodiments. In these embodiments, the doped front side region 102 is configured as an anode region of the second conductivity type. For example, this anode region contiguously extends within the active region 1-2 and is there contacted by the first load terminal 11, which may be embodied as a front side metallization. The doped back side region 108 may be configured as a cathode region of the first conductivity type. For example, this cathode region contiguously extends within the active region 1-2 and also into the edge termination region 1-3 (e.g., until the chip edge 1-4) and is contacted by the second load terminal 11 in both the active region 1-2 and also the edge termination region 1-3, wherein the second load terminal 12 may be embodied as a back side metallization.

Unlike the first load terminal 11, the second load terminal 12 extends into both the active region 1-2 and the edge termination region 1-3, e.g., until the edge 1-4. That is, the electrical connection between the doped back side region 108 and the second load terminal 12 is contiguously established along the entire horizontal area back side area of the semiconductor body 10, in accordance with an embodiment. The electrical connection between the doped front side region 102 and the first load terminal 11 terminates at the transition between the active region 1-2 and the edge termination region 1-3, in accordance with an embodiment and as illustrated in FIGS. 3 and 4.

Presented herein are exemplary configurations of the edge termination region 1-3 at the front side 110, namely, in the semiconductor body 10, VLD region 105 of the second conductivity type, and above thereof and external of the semiconductor body 10 an insulation layer 19 and, above thereof, an electrically conductive conductor 115 coupled to the electrical potential of the first load terminal 11. These three components can be configured as follows:

The VLD (Variation of the Lateral Doping) region 105 can be coupled to the doped front side region 102 and may exhibit a laterally varying dopant concentration that decreases in a direction from the active region 1-2 towards the chip edge 1-4. For example, the VLD region 105 exhibits, in a portion adjacent to the doped front side region 102, a dopant dose of at least 2*10¹² cm⁻². The dopant dose of the VLD region 105 may decrease, along the direction towards the chip edge 1-4, to a minimum of less than 40%, e.g., in a portion of the VLD region 105 that laterally overlaps with the insulation layer 19 and that does not laterally overlap with the conductor 15. The dopant dose of the VLD region 105 may be the integral over the dopant concentration of the atoms of the second conductivity type within the VLD region 105 in the vertical direction Z. The dopant dose (and, accordingly, also the dopant concentration) of the VLD region 105 must not necessarily change along the entire lateral extension of the VLD region, but may be constant for one or more portions of the lateral extension of the VLD region 105. The dopant dose of the VLD region 105 in a portion of the VLD region 105 that laterally overlaps with the conductor 115 does, for example, not fall below 2*10¹² cm⁻². For example, at the transition between the active region 1-2 and the edge termination region 1-3, the doped front side region 102 seamlessly adjoins the VLD region 105. Further, as illustrated, the VLD region 105 does, for example, not extend until the chip edge 1-4, but terminates at a distance of, e.g., at least ⅕ of the semiconductor body thickness d, before the chip edge 1-4. In terms of vertical extension, the VLD region 105 does not extend further along the vertical direction Z than the doped front side region 102, in accordance with an embodiment. In another embodiment, the VLD region 105 extends as far as the front side region 102 along the vertical direction Z, or even further than the front side region 102. For example, the maximal vertical extension of the VLD region 105 is within the range of 25% to 200% of the maximal vertical extension of the doped front side region 102.

In an embodiment, the power semiconductor device 1 comprises, at the insulation layer 19, a semi-insulating layer 159 (cf. FIG. 4). For example, the semi-insulating layer 159 is connected to both the potential of the first load terminal 11 and the potential of the second load terminal 12. Further, the semi-insulating layer 159 is for example based on one or more of the following materials: diamond-like carbon, semi-insulating poly-crystalline, amorphous semiconductor material, semi-insulating polycrystalline silicon, silicon nitride, Si-rich silicon nitride, and Si₃N₄.

The insulation layer 19 can be arranged on top of the front side 110 of the semiconductor body 10, e.g., in contact therewith or coupled thereto via said semi-insulating layer 159 (only illustrated in FIG. 4). In another embodiment, the insulation layer 19 is arranged on top of the front side 110 of the semiconductor body 10 and in direct contact thereto and the semi-insulating layer 159 is arranged on top of the insulation layer 19 and in direct contact thereto. For example, the insulation layer 19 is based on silicon dioxide, SiO₂. The insulation layer 19 can be arranged adjacent to the first load terminal 11, e.g., in contact therewith, and may laterally extends toward the chip edge 1-4 so as to laterally overlap with the VLD region 105. For example, the insulation layer 19 laterally overlaps with the entire VLD region 105 and extends further towards the chip edge 1-4 as the VLD region 105 and/or as the conductor 115. As illustrated in both FIG. 3 and FIG. 4, the VLD region 105 may partially overlap with the peripheral portion of the doped front side region 102. The insulation layer 19 has a thickness ti along the vertical direction Z. For example, the thickness ti is substantially constant along at least 90% of the total lateral extension of the insulation layer along the direction from the active region 1-2 towards the chip edge 1-4.

At the chip edge 110 and on the front side 110, there may be arranged a conductive contact structure 191 exhibiting the potential of the second load terminal 12. For example, this contact structure 191 is arranged in contact with a window in the insulation layer 19, as illustrated in FIG. 4. For example, the conductive contact structure 191 may be arranged only in lateral corners of the semiconductor body 10 or be configured as a ring structure circumscribing the active region 1-2. Further, a conductive channel stop field plate structure 192 may be arranged and top of the insulation layer 19 outside of the lateral termination of the VLD region 105. The conductive channel stop field plate structure 192 may be electrically connected with the conductive contact structure 191.

As indicated above, at the insulation layer 19 and the semiconductor body 10, there may be arranged said semi-insulating layer 159. For example, the semi-insulating layer 159 may be electrically connected to both the potential of the first load terminal 11 and the potential of the second load terminal 12. To this end, the semi-insulating layer 159 may be arranged in contact with the conductive contact structure 191 on the one side and, on the other side, in contact with first load terminal 111. The thickness of the semi-insulating layer 159 is comparatively small, e.g., less than ½ of the thickness t₁ of the insulation layer 19. Further enhancement of the reliability and stability of the edge termination may be achieved based on said semi-insulating layer 159.

On top of the insulation layer 19, there is arranged said electrically conductive conductor 115. The conductor 115 is coupled to the electrical potential of the first load terminal 11. For example, the conductor 115 is arranged in contact with the first load terminal 11 (cf. FIG. 3, according to which the conductor 115 adjoins the first load terminal 11) or a conductive element 111 is employed to establish the electrical connection between the conductor 115 and the first load terminal 11 (cf. FIG. 4). In an embodiment, a metallization used for forming the first load terminal 11 is “laterally extended” so as to form the conductor 115 above the insulation layer 19; in this case, the conductor 115 can be considered to form a portion of the material forming the first load terminal 11. However, unlike the first load terminal 11, the conductor 115 is not arranged in contact with the semiconductor body 10 but separated therefrom based on the insulation layer 19. For the conductor 115 may exhibit a contiguous and non-structured form, e.g., the conductor 115 is an unstructured layer. The conductor 115 may exhibit the potential of the first load terminal 11 in every portion of the conductor 115, e.g., also at the peripheral portion facing to the chip edge 1-4. The conductor 115 laterally overlaps both the insulation layer 19 and the VLD region 105, wherein the lateral overlap between the insulation layer 19 and the VLD region 105 is greater than the lateral overlap between the insulation layer 19 and the conductor 115. Further, the portion of the conductor 115 which laterally overlaps with the VLD region 105 may exhibit a lateral extension lec of at least 50 times or of at least 100 times the thickness ti (along the vertical direction Z) of the insulation layer 19. Additionally, it may be provided that said portion of the conductor 115 which laterally overlaps with the VLD region 105 exhibits a lateral extension lec of at most 400 times or of at most 200 times the thickness ti (along the vertical direction Z) of the insulation layer 19. As already mentioned above, the VLD region 105 may extend further towards the chip edge 1-4 than the conductor 115. For example, the conductor 115 terminates, with respect to the direction from the active region 1-2 towards the chip edge 1-4, at a position where, during a static blocking operation of the power semiconductor device 1, the VLD region 105 is not completely depleted of carriers. The optional aspect is schematically illustrated in FIG. 4, where the dotted line indicates the end of the space charge region during static blocking operation at full blocking voltage (e.g., in case the power semiconductor device 1 is in reverse blocking state). A first subregion 1051 of the VLD region 105, which at least partially laterally overlaps with the conductor 115, can be considered as a non-depletable VLD subregion, and a second subregion 1052 of the VLD region 105, which does not laterally overlap with the conductor 115, can be considered as a graded VLD subregion 1052. In an embodiment, the first subregion 1051 of the VLD region 105 exhibits a dopant dose of at least 2*10¹²/cm² and/or of at most 1*10¹³/cm².

An exemplary alignment of the conductor 115 with respect to the course of the dopant concentration of the VLD region 105 is illustrated in FIG. 5. Adjoining the, e.g. highly, doped front side region 102 in area (1), the VLD region 105 comprises a portion with rather high doping concentration in area (2), for example said first subregion 1051, which is not fully depleted at full static blocking voltage. For example, the VLD region 105 comprises a first homogeneously portion in area (2) and second portion in area (3), wherein in the second portion in area (3), the doping concentration decreases from the dopant concentration of the first homogeneously doped portion (2) towards the chip edge 1-4. The first portion (2) and second portion (3) may be arranged next to each other. For example, when integrating the acceptor concentration starting at the front side 110 (i.e., at the semiconductor surface) into the depth of the device, in area (2) a value of 2*10¹² acceptors/cm² can be exceeded. This doping area may be substantial homogeneous doped or may exhibit some gradient (not illustrated in FIG. 5). Further towards the chip edge 1-4, there is an area (3) where the doping concentration is dropping to a minimum, e.g., in said second subregion 1052 of VLD region 105. The characteristic of the reduction in doping may be linear as shown in FIG. 5 but also polynomial, square-root-shaped, piecewise linear, parabolic or following another characteristic in accordance with another embodiment. In FIG. 5, the minimum is forming a step but it could also fade out into the base material doping of the semiconductor body 10. A breakdown for the edge termination of the VLD region 105 can take place somewhere in area (3), e.g., at position (4).

Still referring to FIG. 5, in an embodiment, the conductor 115 terminates above or within the area (2), e.g., in order to not negatively influence the static blocking behavior, mainly in the presence of humidity. In static blocking behavior, the characteristic of the electric field distribution inside the semiconductor body 10 and also above the semiconductor body 10 in the insulation layer 19 and a (non-illustrated, but optionally present) insulating passivation and/or package layer(s) may be not substantially changed by the conductor 115 compared to a case where the conductor 115 would be missing or only overlap with the insulating layer 19 to comply with manufacturing tolerances to ensure complete covering of the highly doped frontside region 102. For example, the conductor 115 terminates laterally above the first homogeneously doped portion in area (2), such that the conductor 115 overlaps the first homogeneously doped portion (2) but does not overlap the second portion (3).

The above-described configurations of the edge termination region can be in particular advantageous for all types of bipolar power semiconductor devices, e.g., to improve the dynamic ruggedness. In addition, productions costs are reduced.

Presented herein is also a method of producing a power semiconductor device.

For example, the method of producing a power semiconductor device comprises forming the following components: an active region surrounded by an edge termination region, wherein the edge termination region is terminated by a chip edge; a semiconductor body extending in both the active region and the edge termination region and comprising a semiconductor drift region of a first conductivity type; a first load terminal at a front side of the semiconductor body; a second load terminal at a back side of the semiconductor body opposite to the first side, wherein the power semiconductor device is configured to conduct, in the active region and along a vertical direction, a load current between the first load terminal and the second load terminal; in the semiconductor body and electrically connected with the first load terminal at the front side within the active region, a doped front side region of a second conductivity type; in the semiconductor body within the edge termination region, a VLD region of the second conductivity type, wherein the VLD region is coupled to the doped front side region and exhibits a laterally varying dopant concentration that decreases in a direction from the active region towards the chip edge; at the front side, in the edge termination region, adjacent to the first load terminal and laterally overlapping with the VLD region, an insulation layer; and above the insulation layer, in the edge termination region and laterally overlapping with the VLD region at least partially, an electrically conductive conductor coupled to the electrical potential of the first load terminal.

Embodiments of the above-described method correspond to the embodiments of the power semiconductor device 1 described above. Accordingly, these embodiments of the method will not literally be described herein, but it is referred to the above.

For example, the VLD region 105 is formed by carrying out an implantation processing step. For example, when setting up an ion implantation, the dopant dose is selected at the tool. The dopant concentration and the depth of the VLD region 105 then are a consequence of the implanted dose and the diffusion temperature budget, which in case of boron as dopant can also be influenced by segregation of boron into a silicon dioxide.

In an embodiment, the lateral reduction of the VLD dose can be achieved during implantation of the VLD region 105 by gradually reducing the open area of a masking layer (e. g. photo resist) with a maximum in area (2) of FIG. 5 and a reduction in area (3) according to the formula for the decrease. Thus, along a thought line from the doped front side region 102 towards the chip edge 1-4, the masking layer blocks an increasing share of the implanted ions. At a cut-off position, the resist fully blocks the implantation. At the transition from the VLD region 105 to the doped front side region 102 in area (1), the maximum opening area in the VLD resist may overlap a mask window used for implanting the latter to compensate for process tolerances if the doped front side region 102 and VLD region 105 are implanted in different processing steps. In case areas (1) and (2) are diffused in the same high temperature process or processes, due to the lower dose in area (2), area (2) will diffuse less deep into the semiconductor body 10 as area (1).

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGalnN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power semiconductor device, comprising:
an active region surrounded by an edge termination region, wherein the edge termination region is terminated by a chip edge;
a semiconductor body extending in both the active region and the edge termination region, and comprising a semiconductor drift region of a first conductivity type;
a first load terminal at a front side of the semiconductor body;
a second load terminal at a back side of the semiconductor body opposite to the first side, wherein the power semiconductor device is configured to conduct, in the active region and along a vertical direction, a load current between the first load terminal and the second load terminal;
in the semiconductor body and in contact with the first load terminal at the front side within the active region, a doped front side region of a second conductivity type;
in the semiconductor body within the edge termination region, a VLD (variation of the lateral doping) region of the second conductivity type, wherein the VLD region is coupled to the doped front side region and has a laterally varying dopant concentration that decreases in a direction from the active region towards the chip edge;
at the front side, in the edge termination region, adjacent to the first load terminal and laterally overlapping with the VLD region, an insulation layer; and
above the insulation layer, in the edge termination region and laterally overlapping with the VLD region at least partially, an electrically conductive conductor coupled to an electrical potential of the first load terminal.

2. The power semiconductor device of claim 1, wherein the insulation layer laterally overlaps with the doped front side region at least partially.

3. The power semiconductor device of claim 1, wherein the doped front side region adjoins, along a lateral direction, the VLD region.

4. The power semiconductor device of claim 1, wherein the VLD region does not extend further along the vertical direction than the doped front side region.

5. The power semiconductor device of claim 1, wherein the insulation layer extends further towards the chip edge than the VLD region.

6. The power semiconductor device of claim 1, wherein the insulation layer extends further towards the chip edge than the conductor.

7. The power semiconductor device of claim 1, wherein the first load terminal adjoins the conductor, and/or wherein the conductor is a portion of a material forming the first load terminal.

8. The power semiconductor device of claim 1, wherein the conductor has a contiguous and non-structured form.

9. The power semiconductor device of claim 1, wherein the portion of the conductor which laterally overlaps with the VLD region has a lateral extension of at least 50 times a thickness, along the vertical direction, of the insulation layer.

10. The power semiconductor device of claim 1, wherein the portion of the conductor which laterally overlaps with the VLD region has a lateral extension of at most 400 times a thickness, along the vertical direction, of the insulation layer.

11. The power semiconductor device of claim 1, wherein the VLD region extends further towards the chip edge than the conductor.

12. The power semiconductor device of claim 11, wherein the conductor terminates, with respect to a direction from the active region towards the chip edge, at a position where, during a static blocking operation of the power semiconductor device, the VLD region is not completely depleted of carriers.

13. The power semiconductor device of claim 1, wherein the VLD region has, in a portion adjacent to the doped front side region, a dopant dose of at least 2*10¹² cm⁻².

14. The power semiconductor device of claim 1, wherein a dopant dose of the VLD region decreases, along the direction towards the chip edge, to a minimum of less than 40% in a portion of the VLD region that laterally overlaps with the insulation layer and that does not laterally overlap with the conductor.

15. The power semiconductor device of claim 1, wherein a dopant dose of the VLD region in a portion of the VLD region that laterally overlaps with the conductor does not fall below 2*10¹² cm⁻².

16. The power semiconductor device of claim 1, further comprising:
at the insulation layer, a semi-insulating layer connected to both the electrical potential of the first load terminal and an electrical potential of the second load terminal.

17. The power semiconductor device of claim 16, wherein the semi-insulating layer is based on one or more of the following materials: diamond-like carbon, semi-insulating poly-crystalline, amorphous semiconductor material, semi-insulating polycrystalline silicon, silicon nitride, Si-rich silicon nitride, and Si₃N₄.

18. The power semiconductor device of claim 1, further comprising:
in the semiconductor body and electrically connected with the second load terminal at the back side within the active region, a doped back side region,
wherein the semiconductor drift region is arranged between doped front side region and the doped back side region.

19. The power semiconductor device of claim 1, wherein the VLD region comprises a first homogeneously doped portion and a second portion, wherein in the second portion, the doping concentration decreases from the dopant concentration of the first homogeneously doped portion towards the chip edge.

20. The power semiconductor device of claim 19, wherein the conductor terminates laterally above the first homogeneously doped portion, such that the conductor overlaps the first homogeneously doped portion but does not overlap the second portion.

21. The power semiconductor device of claim 1, wherein the power semiconductor device is a diode, the doped front side region is an anode region and the doped back side region is a cathode region of the first conductivity type.

22. A method of producing a power semiconductor device, the method comprising:
forming an active region surrounded by an edge termination region, wherein the edge termination region is terminated by a chip edge;
forming a semiconductor body extending in both the active region and the edge termination region, and comprising a semiconductor drift region of a first conductivity type;
forming a first load terminal at a front side of the semiconductor body;
forming a second load terminal at a back side of the semiconductor body opposite to the first side, wherein the power semiconductor device is configured to conduct, in the active region and along a vertical direction, a load current between the first load terminal and the second load terminal;
forming, in the semiconductor body and electrically connected with the first load terminal at the front side within the active region, a doped front side region of a second conductivity type;
forming, in the semiconductor body within the edge termination region, a VLD region of the second conductivity type, wherein the VLD region is coupled to the doped front side region and has a laterally varying dopant concentration that decreases in a direction from the active region towards the chip edge;
forming, at the front side, in the edge termination region, adjacent to the first load terminal and laterally overlapping with the VLD region, an insulation layer; and
forming, above the insulation layer, in the edge termination region and laterally overlapping with the VLD region at least partially, an electrically conductive conductor coupled to the electrical potential of the first load terminal.
